(19) United States
(12) Patent Application Publication
(10) Pub. No.: US 2017/0040952 A1
(43) Pub. Date: Feb. 9, 2017

(54) CIRCUITS AND METHODS PROVIDING AMPLIFICATION WITH INPUT COMMON MODE VOLTAGE FOLLOWING

(71) Applicant: QUALCOMM Incorporated, San Diego, CA (US)

(72) Inventors: Zongyu Dong, San Diego, CA (US); Matthew David Sienko, San Diego, CA (US); Vijayakumar Dhanasekaran, San Diego, CA (US); Mayur Kantharaj Siddanna, San Jose, CA (US); Wenchang Huang, San Diego, CA (US)

(21) Appl. No.: 14/816,622

(22) Filed: Aug. 3, 2015

(51) Int. Cl. H03F 1/32; H03F 3/45

(52) U.S. Cl. CPC H03F 1/3211; H03F 3/4521; H03F 2203/45072; H03F 2203/45112; H03F 2200/372

(57) ABSTRACT

Methods, systems, and circuits for providing low-noise amplification with input common mode voltage following are disclosed. A circuit includes: an amplifier configured to receive a voltage input having an input common mode voltage and configured to generate a differential voltage output having an output common mode voltage; a feedback circuit in communication with the amplifier, the feedback circuit configured to receive the input common mode voltage and the differential voltage output and to generate a feedback voltage in response to the input common mode voltage and the differential voltage output; and an adjustable current source of the amplifier configured to receive the feedback voltage and to adjust a tail current of the amplifier in response to the feedback voltage.

### TECHNICAL FIELD

This application relates to signal amplifiers, and more specifically, to circuits and methods that amplify signals and follow an input common mode voltage.

### BACKGROUND

As mobile devices begin to provide sophisticated options, such as voice activation and higher-fidelity audio, circuits providing better noise and distortion properties are more desirable. Specifically, some codecs include analog front ends that receive audio input from microphones and audio lines in. As mobile devices begin to provide features such as voice activation, it is desirable to include analog front ends in those codecs, where the analog front ends provide very low input referred noise, low total harmonic distortion (THD), while at the same time managing power consumption in a way that increases battery life for the device.

One example conventional circuit uses a 3-stage amplifier in an analog front end, where the stages are arranged in series so that the second stage receives an amplified signal from the first stage and the third stage receives the amplified signal from the second stage. In the example conventional circuit, the first stage dominates the noise performance and determines the power consumption for the entire three-stage amplifier. Also in this example conventional circuit, the first stage amplifier may work in either a differential mode or a single-ended mode. Working in differential mode, the input virtual ground would be fixed, and the THD performance may suffer some degradation by the input signal, although the degradation may not be significant in some instances. Working in single-ended mode, the input virtual ground may swing, following the input signal common mode voltage, which has the potential to cause headroom issues and thus degrade the THD performance in a significant way.

One traditional approach to amplifiers is to use an auto-zero technique, however an auto-zero technique may increase power consumption to reduce noise. In other words, there may be a trade-off between power consumption and THD performance. Also, a conventional chopping technique may increase parasitic resistance, thereby increasing the thermal noise level and decreasing THD performance.

Accordingly, it would be desirable to use a low-input referred noise and low-power solution at least for a signal amplifier.

### SUMMARY

Methods, systems, and circuits for amplifying signals and following an input common mode voltage are disclosed herein. One example embodiment includes a system having an amplifier circuit and a feedback circuit. The amplifier circuit includes a portion that outputs a differential output signal, which is received by the feedback circuit. The feedback circuit also senses an input common mode voltage from the amplifier circuit. The feedback circuit compares the input common mode voltage to the output common mode voltage and provides a feedback voltage that adjusts a tail current of the amplifier circuit.

The example system operates so that the feedback voltage adjusts the tail current of the amplifier circuit to minimize a difference between the output common mode voltage and the input common mode voltage. The example embodiment provides a system where drain-source voltages of the transistors of the amplifier circuit remain constant even when the input common mode voltage varies. The gain in output of the transistors remains constant over the output of the swing. This may result in a high and fixed again that stays substantially constant despite any changes in the input signal.

In one example embodiment, the input voltage is a differential input voltage. In another example embodiment, the input voltage is a single-ended voltage, where one input signal is a time-varying signal (e.g., an analog signal from a microphone) and the other input signal is connected to ground or a DC bias and does not vary over time. In a single-ended input voltage embodiment, the input common mode voltage may be expected to vary more than it would in a differential input voltage embodiment. Accordingly, the system described herein may provide a low-noise and low-distortion output in both differential and single-ended input embodiments.

In some examples, the system may include a stage in a multi-stage amplifier. For instance, in a three-stage amplifier, the system may be implemented as the first stage, which is usually expected to dominate the noise performance and determine the power consumption of the three-stage amplifier.

Another example embodiment includes a method for operating a system, such as the one described above. The example method includes receiving a voltage input having an input common mode voltage and generating a differential voltage output having an output common mode voltage. A feedback circuit generates a feedback voltage in response to the input common mode voltage and the output common mode voltage. The feedback voltage adjusts a tail current of the amplifier circuit so that the output common mode voltage follows the input common mode voltage.

### BRIEF DESCRIPTION OF THE DRAWINGS

FIG. 1 is a simplified block diagram of an example amplifier system, according to one embodiment.

FIG. 2 is a transistor-level illustration of an example amplifier system, according to one embodiment.

FIG. 3 is an illustration of a three-stage amplifier system, according to one embodiment.

FIG. 4 is an illustration of an example computing device that may include an amplifying system according to FIGS. 1, 2 and 3, according to one embodiment.

FIG. 5 is an illustration of an example method that may be performed by the circuits of FIGS. 1, 2, and 3, according to one embodiment.

### DETAILED DESCRIPTION

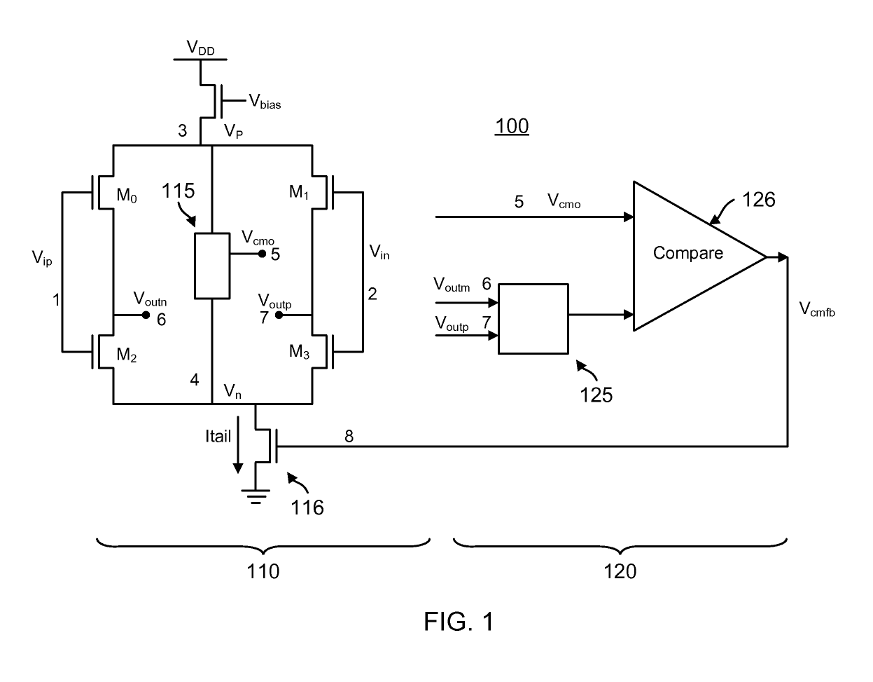

An example embodiment includes an amplifier and a feedback circuit as shown in FIG. 1. As described in more detail below, the feedback circuit senses the input common mode voltage (either directly or indirectly) and the output common mode voltage (either directly or indirectly) and provides a feedback signal to adjust a bias voltage or current of the amplifier so that the output common mode voltage follows the input common mode voltage.

FIG. 1 is an illustration of an example signal amplifying system 100, according to one embodiment. An amplifier circuit 110 is shown on the left, and the feedback circuit 120 is shown on the right. Nodes are identified by numerals 1-8 for simplicity of illustration. The input signal includes two voltage signals (Vip and Vin), shown here at nodes 1 and 2 respectively. The output signal of the amplifier includes two voltages (Voutn and Voutp), shown here at nodes 6 and 7 respectively. The input signal may be a true differential input voltage or a single-ended input voltage. The output signal is a differential voltage.

The amplifier 110 includes four transistors, labeled M0-M3. The two transistors at the top, M0 and M1, are in communication with a voltage at node 3, which may be a source voltage or a drain voltage, depending on how amplifier 110 is designed. The two transistors at the bottom, M2 and M3, are in communication with a voltage at node 4, which (again) may be a source voltage or a drain voltage. The amplifier circuit includes a common mode generating circuit 115 placed between the nodes 3, 4 to provide voltage at node 5. The voltage at node 5 in this example is indicative of the input common mode voltage, and it is provided to the feedback circuit 120 on the right as an input. The input common mode voltage is generally understood to be an average of the voltages at nodes 1 and 2. However, the voltage at node 5 is indicative of the input common mode voltage because it follows the input common mode voltage. In the example of FIG. 1, feedback circuit 120 senses the input common mode voltage indirectly by sensing the voltage at node 5. It is within the scope of embodiments to sense the input common mode voltage either directly or indirectly.

The output signal includes a differential voltage, and the output voltage is represented by the voltages at nodes 6 and 7, where the output common mode is an average of the voltages at nodes 6 and 7. The output signal is also fed to the feedback circuit on the right as an input. Averaging circuit 125 receives the output voltages at nodes 6 and 7 and provides the output common mode voltage to compare circuit 126.

In this example, the feedback circuit 120 includes a compare circuit 126 that generates the feedback voltage at node 8. The feedback voltage at node 8 is an output of the feedback circuit 120, and it is provided to a transistor 116 of the amplifier circuit 110. The transistor 116 acts as an adjustable current source, so that as the voltage at node 8 varies, the tail current (Itail) of the amplifier circuit 110 also varies.

If the input common mode voltage decreases relative to the output common mode voltage, then the feedback voltage at node 8 decreases; if the input common mode voltage increases relative to the output common mode voltage, then the feedback voltage at node 8 increases. An increase in feedback voltage at node 8 causes the tail current Itail to increase as well, which brings down the voltages at nodes 3 and 5. Similarly, a decrease in feedback voltage 8 causes Itail to decrease, which increases the voltages at nodes 3 and 5. In this manner, system 100 causes the output common mode voltage to follow the input common mode voltage 5.

It is expected during normal operation of an amplifier system, especially in embodiments using a single-ended input voltage, that the input common mode voltage may vary (and, thus, so would the voltage at node 5). However, in conventional systems if the input common mode voltage deviates significantly from the output common mode voltage, then the voltages across each of the transistors may become too large and force the transistors into a linear region. This may reduce fidelity of the output signal. The embodiment shown in FIG. 1 provides feedback and adjustment of the tail current so that the output common mode voltage follows the voltage at node 5, and thus follows the input common mode voltage, to maintain a constant or nearly constant voltage across each of the individual transistors M0-M3.

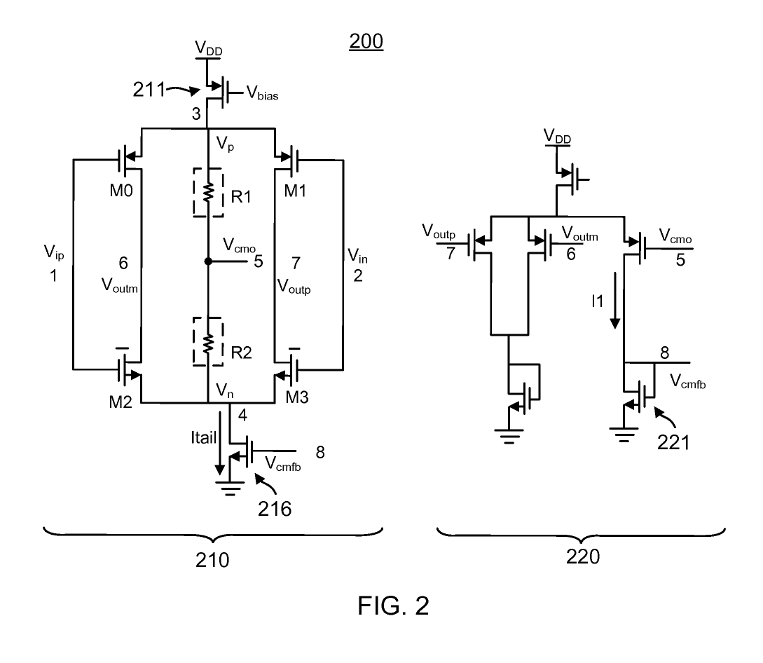

FIG. 1 provides a simplified block diagram embodiment. A more detailed explanation is provided with respect to FIG. 2, which is an illustration of an example amplifier system 200 adapted according to one embodiment. Or put another way, FIG. 2 provides an example circuit architecture for the system of FIG. 1.

In FIG. 2, the nodes 1-8 are labeled in the same manner as in FIG. 1. The amplifier 210 includes four transistors, labeled M0-M3. The two PMOS transistors at the top, M0-M1, have a source voltage at node 3. The two NMOS transistors at the bottom, M2-M3, have a source voltage at node 4. Transistor 211 acts as a constant current source in this example. The amplifier circuit includes a voltage divider (with R1 and R2) placed between the source voltages at nodes 3, 4 to provide the voltage indicative of input common mode voltage at node 5. The voltage at node 5 is provided to the feedback circuit 220 as an input.

In this example, the feedback circuit 220 is an amplifier circuit that generates a current I1 that is proportional to the difference between the average of the voltages nodes 6 and 7 (the output common mode voltage) and voltage at node 5. The current I1 is provided to transistor 221, thereby producing the feedback voltage at node 8. Just as in FIG. 1, when the input common mode voltage decreases relative to the output common mode voltage, then the feedback voltage at node 8 decreases; when the input common mode voltage increases relative to the output common mode voltage, then the feedback voltage at node 8 increases.

The feedback voltage at node 8 is an output of the feedback circuit 220, and it is provided to transistor 216 of the amplifier 210. The transistor 210 is an adjustable current source that varies Itail as voltage 8 varies. The scope of embodiments is not limited to a transistor that varies a tail current. The transistor 210 is an example of a bias component that adjusts a bias (either voltage or current) to adjust the output common mode voltage.

The embodiment of FIG. 2 causes the output common mode voltage (the average of the voltages at nodes 6 and 7) to follow the voltage at node 5 (thus following the input common mode voltage), thereby maintaining a constant or nearly constant source-drain voltage at each of the transistors M0-M3. As one example, as the tail current Itail increases, it causes the PMOS source voltage at node 3 to go down, and the voltage at node 5 goes down as well, which is sensed by the feedback circuit 220. In response, the feedback circuit 220 reduces the tail current Itail to move those voltages (at nodes 3, 4, 6, 7) back up. Similarly, as the tail current Itail decreases, it causes the PMOS source voltage at node 3 to increase, which also causes the voltage at node 5 to increase. This is sensed by the feedback circuit 220, which increases the tail current to move those voltages (at nodes 3, 4, 6, 7) down.

As discussed above, the amplifier circuit 210 includes a differential input stage, where the output common mode voltage (an average of voltages at nodes 6, 7) follows the voltage at node 5 to create fixed bias points across the input transistors M0-M3 to support a varying input common mode voltage. Since the bias points across the transistors M0-M3 are constant or substantially constant, the amplifier can act as a low noise and low harmonic distortion amplifying stage.

The scope of embodiments is not limited to the specific structure shown in FIG. 2. For instance, while amplifier stage 210 includes a resistor divider having R1 and R2 to provide a voltage indicative of the input common mode voltage at node 5, any appropriate technique for sensing an input common mode voltage at the feedback circuit 220 may be used. Also, The ratio of R1:R2 can be designed to realize various output common mode voltages. Furthermore, while the circuit of FIG. 2 senses an average of the voltages at nodes 6 and 7, the average is not the only ratio of the voltages at nodes 6 and 7 that may be used. In other words, other embodiments may use any appropriate weighted average of voltages at nodes 6 and 7.

The circuit of FIG. 2 may be manufactured using any appropriate transistor technology. For instance, CMOS technology may be used in some embodiments to build the transistors used in amplifier circuit 210 and feedback circuit 220. Furthermore, C²MOS with native NMOS may provide good noise performance in some applications. In the example of FIG. 2, transistors M2 and M3 are shown as native NMOS devices.

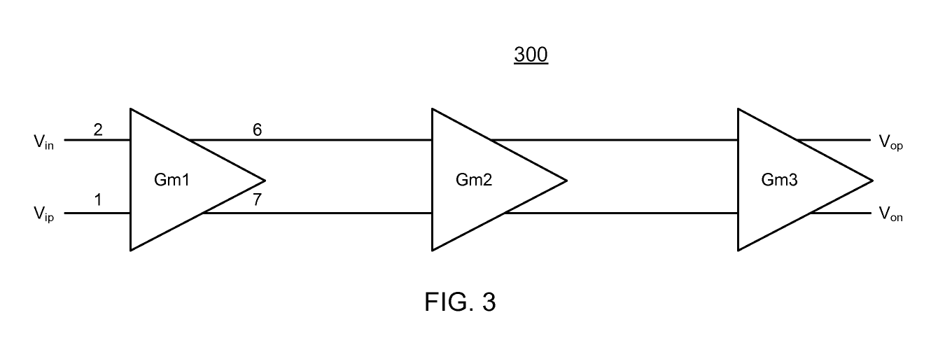

FIG. 3 is an illustration of an example application of the amplifier systems 100 and 200 (FIGS. 1 and 2), according to one embodiment. FIG. 3 illustrates a three-stage amplifier system 300. The first amplifier stage is labeled Gm1, and it amplifies an input signal and then passes the amplified input signal to the second stage, Gm2. Gm2 provides further gain and then sends its output to the input of the third stage, Gm3. Gm3 provides the final stage of gain and outputs differential voltages VOP and VON.

In the example of FIG. 3, the first amplification stage Gm1 includes an amplifier system according to the principles discussed above with respect to FIGS. 1 and 2. For convenience, voltages at nodes 1, 2, 6, and 7 (discussed above with respect to FIGS. 1 and 2) are labeled in FIG. 3. Amplifier stage Gm1 receives the two input voltages at nodes 1 and 2 and provides a differential output voltage at nodes 6 and 7. As discussed above, the input voltage at nodes 1 and 2 may be a differential voltage or may be single-ended. In a single-ended embodiment, the voltage at node 2 may be a ground or DC bias, whereas the voltage at node 1 includes an analog input signal that varies with time.

The first amplifier stage Gm1 includes the feedback technique discussed above, where the output common mode voltage follows the input common mode voltage. This may be helpful because the feedback technique discussed above with respect to FIGS. 1 and 2 provides for low-noise and low harmonic distortion but without a substantial increase in power, and certainly less power consumption than would be expected using an auto-zero technique or a chopping technique. In a system such as that shown in FIG. 3, the first gain stage Gm1 would be expected to dominate the noise performance and determine the power consumption of the entire system 300. Accordingly, the techniques of FIGS. 1 and 2 may be advantageous in such embodiments by providing acceptable noise performance without substantial increase in power consumption. The other gain stages, Gm2 and Gm3, may be embodied using any acceptable amplifier techniques.

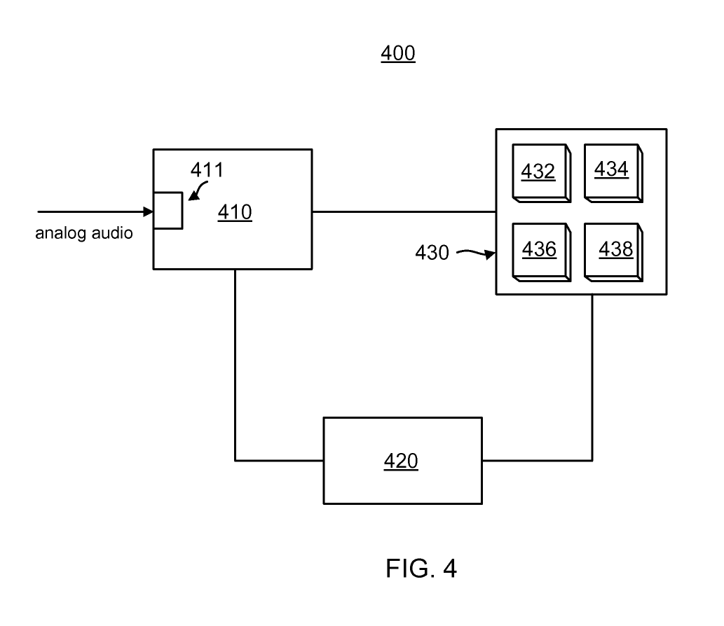

FIG. 4 is an illustration of an example application of the amplifier systems 100 and 200 (FIGS. 1 and 2) according to one embodiment. Specifically, FIG. 4 is a simplified block diagram of a computing device 400. Computing device 400 may include any appropriate computing device, such as a smart phone, a tablet computer, a laptop computer, or the like.

Computing device 400 includes a coder/decoder (codec) 410, which receives an analog audio input at its analog front end 411. In short, codec 410 receives an analog signal, converts the signal to a digital signal and encodes it appropriately. Codec 410 then passes the encoded digital signal to a system on chip (SOC) 430. Similarly, codec 410 may receive encoded digital signals from SOC 430, decode and convert those signals to analog before passing them to an analog output (not shown) or a transducer such as a speaker (not shown).

Analog front end 411 is configured to receive the analog audio signal. Examples of analog audio signals include but are not limited to microphone inputs and audio line-in inputs. Analog front end 411 receives the analog audio signal and provides an appropriate amount of gain before outputting the signal to an analog to digital converter (not shown).

In one particular implementation, the analog front end 411 includes a three-stage amplifier, such as that shown in FIG. 3. As noted above, the amplifier of FIG. 3 may include the amplifying and feedback arrangement described above with respect to FIGS. 1 and 2. In the amplifier as described above, the output common mode voltage follows the input common mode voltage through a feedback mechanism, which allows for low noise and low harmonic distortion performance. Such features may be advantageous in the embodiment of FIG. 4, where the codec 410 may receive an analog audio signal having a relatively high dynamic range such as a signal including both loud voices and quiet voices. The low-noise amplification discussed above may allow for the analog signal to be adjusted for gain in output as a differential analog signal with high fidelity, allowing for accurate digital conversion and precise processing.

SOC 430 includes in this example a multitude of cores 432-438. In this example, the cores 432-438 may include any appropriate computing core, where examples include a mobile station modem, a central processing unit (CPU), a graphics processing unit (GPU), a digital signal processor (DSP), a 802.11x modem, or the like. In some examples, SOC 430 is specifically made for a mobile device, such as a smart phone, such that cores 432-438 are designed for low power consumption. However, the scope of embodiments is not limited to any specific SOC architecture.

Computing device 400 also includes power management circuit 420. In some examples, power management circuit 420 may include a power management integrated circuit (PMIC) or other appropriate circuit operable to convert power to a voltage that is appropriate for use by codec 410 and SOC 430. Furthermore, while FIG. 4 shows only a single power management circuit 420, it is understood that various embodiments may include any appropriate number of power management circuits to provide power to the various processing units.

Also, the scope of embodiments is not limited to the specific architecture shown in FIG. 4. Computing device 400 may include any appropriate number of codecs, SOCs, and or other devices. Moreover, while codec 410, power management circuit 420, and SOC 430 are shown as being separate, it is understood that the scope of embodiments is not limited to any particular packaging arrangement or integration arrangement.

Various embodiments may include one or more advantages over conventional solutions. For instance, some of the embodiments described herein allow for similar noise and harmonic distortion performance that would be achieved with conventional chopping or auto-zero techniques but with less power consumption. Such features may allow the circuits described above to be implemented in advanced mobile devices, which are designed for low power consumption and precise audio performance.

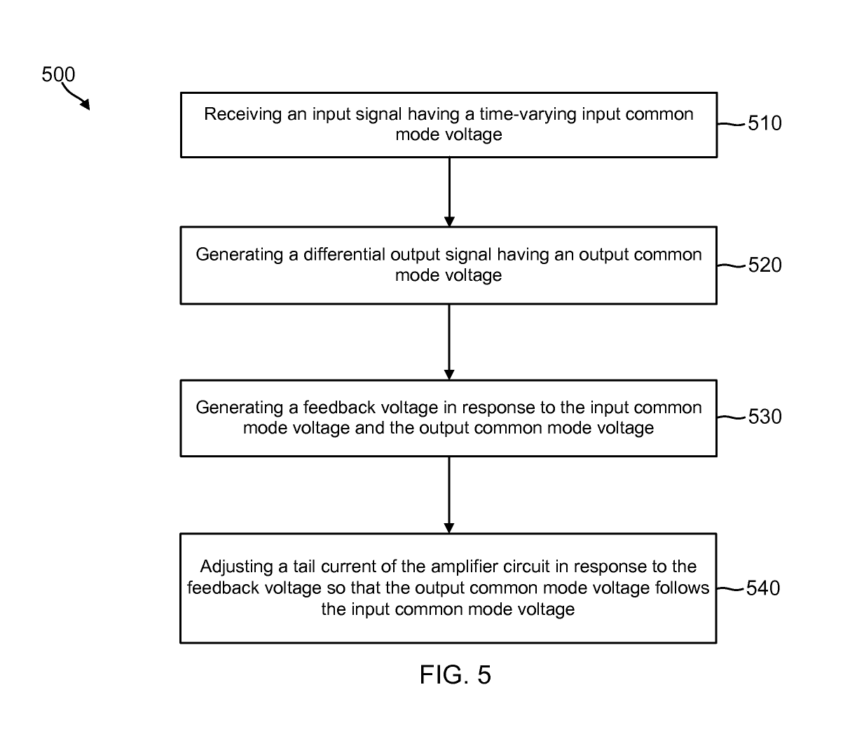

FIG. 5 is an illustration of an example method 500, according to one embodiment. Method 500 may be performed by circuits, such as those shown in FIGS. 1 and 2. Specifically, an amplifier system (e.g., system 100 or system 200) that receives an input signal at a first voltage and adjusts a gain of the input signal, thereby providing the input signal at a second voltage, may perform method 500.

At action 510, the amplifier system receives an input signal having a time-varying input common mode voltage. An example is illustrated at FIG. 1, where the amplifier circuit 110 receives an input signal at Vip and Vin (voltages at nodes 1 and 2). The input signal may be provided as a differential input signal or a single-ended input signal. In either case, the input signal has common mode voltage.

The common mode voltage includes a component of the input signal that is present with one sign on both conductors of the conductor pair. The common mode voltage is one-half of the vector sum of the voltages of each conductor. In instances wherein the input signal is a differential signal, it may be expected that the input common mode voltage, although varying, is relatively constant over the dynamic range of the input signal. However, where the input signal is a single-ended signal, the input common mode voltage may vary as the input signal varies.

Action 510 may also include sensing the input common mode voltage at a feedback circuit. An example is shown in FIG. 2, where a voltage divider includes an output for the voltage at node 5. The feedback circuit 210 senses the voltage at node 5, thereby indirectly sensing the input common mode voltage.

At action 520, the amplifier system generates a differential output signal having an output common mode voltage. An example is shown in FIG. 2, where amplifier circuit 210 adjusts the gain of the input signal to provide a differential output signal at nodes 6 and 7. As explained above, the output common mode voltage follows the input common mode voltage.

At action 530, the amplifier system generates a feedback voltage in response to the input common mode voltage and the output common mode voltage. An example is shown at FIG. 1, where the feedback circuit 110 receives the voltage indicative of the input common mode voltage at node 5 and the differential output signal at nodes 6 and 7. Averaging circuit 125 receives the voltages at nodes 6 and 7 and generates the output common mode voltage therefrom. In an alternative embodiment, the feedback circuit 110 may receive the output common mode voltage itself rather than receiving the output voltage. In such an embodiment, the feedback circuit may not include an averaging circuit 125. The compare circuit 126 senses the input common mode voltage indirectly through the voltage at node 5 and the output common mode voltage and produces the feedback voltage at node 8 in response. As the input common mode voltage decreases relative to the output common mode voltage, the feedback voltage at node 8 decreases. As the input common mode voltage increases relative to the output common mode voltage, the feedback voltage at node 8 increases.

While FIG. 1 shows feedback circuit 120 as a block diagram, FIG. 2 shows an implementation of a feedback circuit 220 from a transistor-level perspective. In FIG. 2, feedback circuit 220 is an amplifier circuit that generates a current I1 that is proportional to the difference between the average of the voltages of nodes 6 and 7 and the voltage indicative of the common mode input voltage at node 5. The current I1 is provided to the transistor 221 to generate the feedback voltage 8.

At action 540, the amplifier system adjusts a tail current of an amplifier circuit in response to the feedback voltage. The adjustment of the tail current causes the output common mode voltage to follow the input common mode voltage. Adjusting a tail current of an amplifier circuit is just one example of adjusting the output common mode voltage. Other embodiments may use any bias component to change a voltage or current in order to adjust the output common mode voltage.

An example is shown at FIGS. 1 and 2, where the voltages across transistors M0-M3 move up or down together in response to changes in the tail current Itail. An increase in the feedback voltage at node 8 causes an increase in the tail current Itail, and a decrease in feedback voltage at node 8 causes a decrease in the tail current Itail. As one example, as the common mode input voltage decreases, it is sensed by the feedback circuit 110 or 210. In response, the feedback circuit 110 or 210 reduces the feedback voltage at node 8 to move the voltages at nodes 3, 4, 6, 7 up. Similarly, as the common mode voltage increases, it is sensed by the feedback circuit 110 or 210, which increases the feedback voltage at node 8 to move the voltages at nodes 3, 4, 6, 7 down.

In this manner, the amplifier circuit 110 and the feedback circuit 120 form a feedback loop in which a difference between the common mode input voltage and the output common mode voltage affects the tail current Itail so that the output common mode voltage follows the input common mode voltage. However, the drain-source voltages of the transistors M0-M3 remains relatively constant, even though the input signal may vary.

The scope of embodiments is not limited to the actions shown in FIG. 5. Other embodiments may add, omit, modify, or rearrange one or more actions. For example, FIG. 5 illustrates a series of actions. However, during operation of the circuits of FIGS. 1 and 2, the actions occur substantially simultaneously as the analog circuits adjust and react to changes in the voltages. Furthermore, the actions described above may be performed continuously as an amplifier circuit receives a varying input signal.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

1. A circuit comprising:
an amplifier configured to receive an input signal having an input common mode voltage that is time-varying, and the amplifier is configured to generate a differential output signal having an output common mode voltage;
a feedback circuit in communication with the amplifier, the feedback circuit configured to sense the input common mode voltage and the output common mode voltage and to generate a feedback voltage in response to the input common mode voltage and the output common mode voltage; and
an adjustable bias component of the amplifier configured to receive the feedback voltage and to adjust the output common mode voltage in response to the feedback voltage so that the output common mode voltage follows the input common mode voltage; and
a common mode generating circuit disposed between a current source of the amplifier and the adjustable bias component, the common mode generating circuit configured to generate a common mode voltage signal, wherein the feedback circuit is configured to sense the input common mode voltage from the common mode voltage signal.

2. The circuit of claim 1, wherein the adjustable bias component comprises:
an adjustable current source configured to receive the feedback voltage and to adjust a tail current of the amplifier in response to the feedback voltage.

3. The circuit of claim 1, wherein the amplifier comprises:
a first PMOS transistor and a first NMOS transistor configured to receive a first voltage of the input signal and arranged such that a source of the first PMOS transistor is in communication with a constant current source and a source of the first NMOS transistor is in communication with the adjustable current source; and
a second PMOS transistor and a second NMOS transistor configured to receive a second voltage of the input signal and arranged such that a source of the second PMOS transistor is in communication with the constant current source and a source of the second NMOS transistor is in communication with the adjustable current source.

4. The circuit of claim 3, wherein:
the common mode generating circuit comprises a resistor divider disposed between the sources of the first PMOS transistor and second PMOS transistor and the sources of the first NMOS transistor and second NMOS transistor, the resistor divider configured to provide a voltage indicative of the input common mode voltage to the feedback circuit.

5. The circuit of claim 1, wherein the feedback circuit comprises:
a feedback amplifier configured to generate a current proportional to a difference between the output common mode voltage and the input common mode voltage.

6. The circuit of claim 5, further comprising:
a transistor configured to receive the current proportional to a difference between the output common mode voltage and the input common mode voltage and to generate the feedback voltage in response thereto.

7. The circuit of claim 1, wherein the circuit is included in a coder/decoder (codec).

8. The circuit of claim 1, wherein the circuit comprises a first amplifier stage of a three-stage amplifier.

9. The circuit of claim 1, wherein the amplifier includes a first input and a second input, wherein the first and second input are configured as a differential input.

10. A method comprising:
receiving an input signal having an input common mode voltage that is time-varying, the input signal received at an amplifier circuit;
generating a differential output voltage having an output common mode voltage;
providing a voltage indicative of the input common mode voltage to a feedback circuit through a voltage divider of on amplifier circuit;
generating by the feedback circuit a feedback voltage in response to the voltage indicative of the input common mode voltage and the output common mode voltage; and
adjusting a bias voltage-or current of the amplifier circuit in response to the feedback voltage so that the output common mode voltage follows the input common mode voltage.

11. The method of claim 10, wherein the input signal comprises a differential.

12. The method of claim 10, wherein the voltage input comprises a differential voltage.

13. The method of claim 10, wherein generating a feedback voltage comprises:
generating a current proportional to a difference between the output common mode voltage and the voltage indicative of the input common mode voltage; and
generating the feedback voltage proportional to the current.

14. The method of claim 10, wherein adjusting the bias voltage or current comprises:
increasing a tail current of the amplifier circuit, causing source voltages at transistors of the amplifier circuit to decrease and causing the input common mode voltage to decrease.

15. The method of claim 10, wherein adjusting the bias voltage or current comprises:
decreasing a tail current of the amplifier circuit, causing source voltages at transistors of the amplifier circuit to increase and causing the input common mode voltage to increase.

16. The method of claim 10, wherein generating the differential output voltage comprises providing a first gain stage of a three-stage amplifier.

17. (canceled)

18. The method of claim 10, wherein the amplifier circuit includes two PMOS transistors receiving the input signal and two NMOS transistors receiving the input signal, wherein:
the voltage indicative of the input common mode voltage includes a voltage average of a source voltage of the two NMOS transistors and a source voltage of the two PMOS transistors.

19. An analog front end circuit comprising:
means for receiving an input signal having an input common mode voltage that is time-varying, the input signal received at an amplifier circuit;
means for generating a voltage indicative of the input common mode voltage;
means for generating a differential output voltage having an output common mode voltage;
means for generating a feedback voltage in response to the voltage indicative of the input common mode voltage and the output common mode voltage; and
means for adjusting a bias voltage or current of the amplifier circuit in response to the feedback voltage so that the output common mode voltage follows the input common mode voltage.

20. The analog front end circuit of claim 19, wherein the means for receiving the input signal comprises:
a first PMOS transistor and a first NMOS transistor configured to receive a first voltage of the input signal and arranged such that a source of the first PMOS transistor is in communication with a constant current source and a source of the first NMOS transistor is in communication with the means for adjusting the tail current; and
a second PMOS transistor and a second NMOS transistor configured to receive a second voltage of the input signal and arranged such that a source of the second PMOS transistor is in communication with the constant current source and a source of the second NMOS transistor is in communication with the means for adjusting the tail current.

21. The analog front end circuit of claim 20, wherein the means for generating a voltage indicative of the input common mode voltage comprises:
a resistor divider disposed between the sources of the first PMOS transistor and second PMOS transistor and the sources of the first NMOS transistor and second NMOS transistor, the resistor divider configured to provide the voltage indicative of the input common mode voltage to the means for generating the feedback voltage.

22. The analog front end circuit of claim 19, wherein the means for generating the feedback voltage comprises:
a feedback amplifier configured to generate a current proportional to a difference between the output common mode voltage and the voltage indicative of the input common mode voltage.

23. The analog front end circuit of claim 22, wherein the means for generating the feedback voltage further comprises:
a transistor configured to receive the current proportional to a difference between the output common mode voltage and the voltage indicative of the input common mode voltage and to generate the feedback voltage in response thereto.

24. The analog front end circuit of claim 19, wherein the analog front end circuit is included in a coder/decoder (codec).

25. The analog front end circuit of claim 19, wherein the analog front end circuit comprises a first amplifier stage of a three-stage amplifier.

26. The analog front end circuit of claim 19, wherein the means for receiving the input voltage comprises means for receiving a differential input voltage.

27. A circuit comprising:
an amplifier circuit including:
a first PMOS transistor and a first NMOS transistor in communication with a constant current source and an adjustable current source and configured to receive a first signal of a voltage input;
a second PMOS transistor and a second NMOS transistor in communication with the constant current source and the adjustable current source and configured to receive a second signal of the voltage input, wherein the voltage input includes a time-varying input common mode voltage; and
a common mode generating circuit disposed between sources of the first and second PMOS transistors and sources of the first and second NMOS transistors and configured to generate an input common mode voltage signal; and
a feedback circuit configured to sense the input common mode voltage signal and an output common mode voltage of the amplifier circuit, the feedback circuit including:
a feedback amplifier configured to generate a current proportional to a difference between the output common mode voltage and the input common mode voltage; and
a transistor configured to receive the current and to generate a bias voltage to adjust a current of the adjustable current source so that the output common mode voltage follows the input common mode voltage.

28. The circuit of claim 27, wherein the amplifier circuit includes a first input and a second input, wherein the first and second input are configured as a differential input.

29. The circuit of claim 27, wherein the input common mode voltage signal comprises a voltage indicative of the input common mode voltage.

30. The circuit of claim 27, wherein the circuit comprises an analog front end of a coder/decoder (codec).
